(19) United States
(12) Patent Application Publication
(10) Pub. No.: US 2024/0302422 A1
(43) Pub. Date: Sep. 12, 2024

(54) METHOD AND SYSTEM FOR ESTIMATING VOLTAGE SUPPORT STRENGTH OF RENEWABLE ENERGY GRID-CONNECTED POWER SYSTEM, AND STORAGE MEDIUM AND ELECTRONIC DEVICE

(71) Applicant: China Electric Power Research Institute, Beijing (CN)

(72) Inventors: Huadong SUN, Beijing (CN); Lin YU, Beijing (CN); Bing ZHAO, Beijing (CN); Shiyun XU, Beijing (CN)

(21) Appl. No.: 18/573,495

(22) PCT Filed: Dec. 5, 2022
(86) PCT No.: PCT/CN2022/136472

§ 371 Date: Dec. 22, 2023

(30) Foreign Application Priority Data
Dec. 10, 2021 (CN) 202111502749.2

(51) Int. Cl. G01R 31/08; G01R 31/52

(52) U.S. Cl. CPC G01R 31/086; G01R 31/52

(57) ABSTRACT

A method for estimating a voltage support strength of a renewable energy grid-connected power system. A first short-circuit ratio index of a renewable energy grid-connected power system is determined based on a short-circuit capacity provided for a grid connection point by an alternating-current system, An equivalent grid connection capacity of renewable energy at the grid connection point is determined. A second short-circuit ratio index of the renewable energy grid-connected power system is determined based on a voltage variation at a position where the renewable energy is connected to the grid connection point. A critical short-circuit ratio of the renewable energy grid-connected power system determined based on a parameter of the alternating-current system and an equivalent maximum transmission power. A voltage support strength provided by the renewable energy grid-connected power system at the grid connection point is determined based on the first and second short-circuit ratio indexes and the critical short-circuit ratio.

### CROSS-REFERENCE TO RELATED APPLICATIONS

This application is filed based on and claims priority to Chinese Patent application No. 202111502749.2 filed on Dec. 10, 2021 and entitled “METHOD AND SYSTEM FOR ESTIMATING VOLTAGE SUPPORT STRENGTH OF RENEWABLE ENERGY GRID-CONNECTED POWER SYSTEM”, the contents of which are hereby incorporated by reference in its entirety.

### TECHNICAL FIELD

The disclosure relates to the technical field of a stability analysis for grid-connection of a renewable energy, and in particular to a method and system for estimating a voltage support strength of a renewable energy grid-connected power system, a storage medium and an electronic device.

### BACKGROUND

Large-scale developments of renewable energies in China are concentrated in western, northern and other regions. Wind power and photovoltaic units have low voltage regulation capacities, they are easily off-grid due to voltage fluctuations when they are connected to weak power grids, and they require systems to provide voltage support. A short-circuit ratio (SCR) is an important index to judge a voltage support strength of the power system. A critical short-circuit ratio (CSCR) is a short-circuit ratio corresponding to a critical stable state of the power system. By comparing a current SCR of the power system with the CSCR of the power system, an operation state of the power system may be judged, and the voltage support strength of the power system may be estimated, which is helpful to control impacts of grid connections of the renewable energies and is of great significance to ensure a safe and stable operation of a renewable energy grid-connected power system.

At present, as an important index for estimating a voltage support strength of the renewable energy grid-connected power system, the SCR has a contradiction between accuracy and practicability; moreover, calculations of the CSCR are inconsistent due to multiple construction methods, which are difficult to provide an accurate, rapid, intuitive and practical method for estimating the voltage support strength of the renewable energy grid-connected power system.

With respect to the above technical problem that it is difficult to provide an accurate, rapid, intuitive and practical method for estimating the voltage support strength of the renewable energy grid-connected power system in the related art, no effective solution has been proposed at present.

### SUMMARY

With respect to the above technical problem that it is difficult to provide an accurate, rapid, intuitive and practical method for estimating the voltage support strength of the renewable energy grid-connected power system in the related art, the disclosure provides a method and system for estimating a voltage support strength of a renewable energy grid-connected power system, a storage medium and an electronic device.

According to an aspect of the disclosure, there is provided a method for estimating a voltage support strength of a renewable energy grid-connected power system, including the following operations.

A first short-circuit ratio index of the renewable energy grid-connected power system is determined based on a short-circuit capacity provided for a grid connection point by an alternating-current (AC) system in the renewable energy grid-connected power system and an equivalent grid connection capacity of a renewable energy at the grid connection point.

A second short-circuit ratio index of the renewable energy grid-connected power system is determined based on a voltage variation at a position where the renewable energy is connected to the grid connection point.

A critical short-circuit ratio (CSCR) of the renewable energy grid-connected power system is determined based on parameters of the AC system and an equivalent maximum transmission power transmitted to the AC system by the renewable energy.

A voltage support strength provided by the renewable energy grid-connected power system at the grid connection point is determined based on the first short-circuit ratio index, the second short-circuit ratio index and the CSCR and by using a preset voltage support strength estimation rule.

In some embodiments, the operation of determining the first short-circuit ratio index of the renewable energy grid-connected power system based on the short-circuit capacity provided for the grid connection point by the AC system in the renewable energy grid-connected power system and the equivalent grid connection capacity of the renewable energy at the grid connection point may include the following operations.

The short-circuit capacity provided for the grid connection point by the AC system in the renewable energy grid-connected power system is determined.

The equivalent grid connection capacity of the renewable energy at the grid connection point is determined.

The first short-circuit ratio index of the renewable energy grid-connected power system is determined based on the short-circuit capacity and the equivalent grid connection capacity.

In some embodiments, the short-circuit capacity provided for the grid connection point by the AC system may be calculated by a formula:

$${\dot{S}}_{ac , i} = \frac{{U}_{N} {\dot{E}}_{eq , i}}{{\dot{Z}}_{ii}}$$

here Ė_{eq,i} is a no-load operation open-circuit voltage of a grid connection point i before the AC system ignores a comprehensive load and the renewable energy is grid-connected; Żᵢᵢ is a diagonal element in an impedance matrix of the grid connection point, which is an equivalent impedance of the AC system to the grid connection point i; and U_{N} is a nominal voltage of the grid connection point i.

In some embodiments, the equivalent grid connection capacity at the grid connection point may be calculated by a formula:

$${\dot{S}}_{eq , i} = {\dot{U}}_{i} {I}_{eq , i}^{*} = {\dot{S}}_{i} + {\sum }_{j \neq i} \frac{{\dot{Z}}_{ij}^{*}}{{\dot{Z}}_{ii}^{*}} \frac{{\dot{U}}_{i}}{{\dot{U}}_{j}} {\dot{S}}_{j}$$

here * represents a conjugate operation; \dot{S}ⱼ, \dot{S}ᵢ are capacities of renewable energies directly connected to grid connection points i and j; I_{eq,i} is a line current of the grid connection point i; Żᵢⱼ is a non-diagonal element in an impedance matrix of the grid connection point, which reflects an electrical distance between the grid connection points i and j; Żᵢᵢ is a diagonal element in the impedance matrix of the grid connection point, which is an equivalent impedance of the AC system to the grid connection point i; and \dot{U}ᵢ, \dot{U}ⱼ are node voltages of the grid connection points i and j.

In some embodiments, the first short-circuit ratio index of the renewable energy grid-connected power system may be calculated by a formula:

$$SCR - {S}_{j} = \frac{{\dot{S}}_{ac , i}}{{\dot{S}}_{eq , i}} = \frac{\vert {U}_{N} {\dot{E}}_{eq , i} / {\dot{Z}}_{ii} \vert}{\vert {\dot{S}}_{i} + {\sum }_{j \neq i} \frac{{\dot{Z}}_{ij}^{*}}{{\dot{Z}}_{ii}^{*}} \frac{{\dot{U}}_{i}}{{\dot{U}}_{j}} {\dot{S}}_{j} \vert}$$

here SCR-Sᵢ is the first short-circuit ratio index of the renewable energy grid-connected power system; \dot{S}_{ac,j} is a short-circuit capacity provided for a grid connection point i by the AC system; \dot{S}_{eq,i} is an equivalent grid connection capacity of the renewable energy at the grid connection point i; \dot{U}ᵢ, \dot{U}ⱼ are node voltages of grid connection points i and j; U_{N} is a nominal voltage of the grid connection point i; Ė_{eq,j} is a no-load operation open-circuit voltage of the grid connection point i before the AC system ignores a comprehensive load and the renewable energy is grid-connected; Żᵢᵢ is a diagonal element in an impedance matrix of the grid connection point, which is an equivalent impedance of the AC system to the grid connection point i; Żᵢⱼ is a non-diagonal element in the impedance matrix of the grid connection point, which reflects an electrical distance between the grid connection points i and j; and \dot{S}ᵢ, \dot{S}ⱼ are capacities of renewable energies directly connected to the grid connection points i and j.

In some embodiments, the operation of determining the second short-circuit ratio index of the renewable energy grid-connected power system based on the voltage variation at the position where the renewable energy is connected to the grid connection point may include the following operations.

A voltage order-reduction equation of the grid connection point is determined when the renewable energy is connected to the grid connection point.

The voltage variation at the position where the renewable energy is connected to the grid connection point, is determined based on the voltage order-reduction equation.

A nominal voltage of the grid connection point is determined.

The second short-circuit ratio index of the renewable energy grid-connected power system is determined based on the voltage variation and the nominal voltage.

In some embodiments, the voltage order-reduction equation of the grid connection point may be:

$$[ \begin{matrix}Δ {\dot{U}}_{1} \\ ⋮ \\ Δ {\dot{U}}_{i} \\ ⋮ \\ Δ {\dot{U}}_{m}\end{matrix} ] = [ \begin{matrix}{\dot{Z}}_{11} & … & {\dot{Z}}_{1 i} & … & {\dot{Z}}_{1 m} \\ ⋮ & & ⋮ & & ⋮ \\ {\dot{Z}}_{i 1} & … & {\dot{Z}}_{ii} & … & {\dot{Z}}_{im} \\ ⋮ & & ⋮ & & ⋮ \\ {\dot{Z}}_{1 m} & … & {\dot{Z}}_{mi} & … & {\dot{Z}}_{mm}\end{matrix} ] [ \begin{matrix}{\dot{I}}_{E , 1} \\ ⋮ \\ {\dot{I}}_{E , i} \\ ⋮ \\ {\dot{I}}_{E , m}\end{matrix} ]$$

here Ż is an impedance matrix of the grid connection point; Δ\dot{U} is a voltage variation at the grid connection point caused when the renewable energy is grid-connected; İᵥ is a current injected by the renewable energy; and m is a serial number of the grid connection point.

In some embodiments, the voltage variation at the position where the renewable energy is connected to the grid connection point may be calculated by a formula:

$$Δ {\dot{U}}_{i} = {\dot{Z}}_{ii} {\dot{I}}_{E , i} + {\sum }_{j \neq i} {\dot{Z}}_{ij} {\dot{I}}_{E , j}$$

here Δ\dot{U}ᵢ is a voltage variation of the grid connection point i; İ_{E,i}, İ_{E,j} are currents injected by the renewable energy into grid connection points i, j; Żᵢᵢ is a diagonal element in an impedance matrix of the grid connection point, which is an equivalent impedance of the AC system to the grid connection point i; and Żᵢⱼ is a non-diagonal element in the impedance matrix of the grid connection point, which reflects an electrical distance between the grid connection points i and j.

In some embodiments, the operation of determining the second short-circuit ratio index of the renewable energy grid-connected power system based on the voltage variation and the nominal voltage may include the following operations.

A formula of calculating a ratio of the nominal voltage to the voltage variation is determined.

The formula of calculating the ratio of the nominal voltage to the voltage variation is further derived, and the second short-circuit ratio index of the renewable energy grid-connected power system is determined.

Here the ratio of the nominal voltage to the voltage variation is calculated by a formula:

$$\frac{\vert {U}_{N} \vert}{\vert Δ {\dot{U}}_{i} \vert} = \frac{\vert {U}_{N} \vert}{\vert {\dot{Z}}_{ii} {\dot{I}}_{E , i} + {\sum }_{{j}^{′} i} {\dot{Z}}_{ij} {\dot{I}}_{E , i} \vert}$$

here U_{N} is a nominal voltage of the grid connection point i; Δ\dot{U}ᵢ is the voltage variation of the grid connection point i; İ_{E,j}, İ_{E,i} are the currents injected by the renewable energy into the grid connection points i, j; Żᵢᵢ is the diagonal element in the impedance matrix of the grid connection point, which is the equivalent impedance of the AC system to the grid connection point i; and Żᵢⱼ is the non-diagonal element in the impedance matrix of the grid connection point, which reflects the electrical distance between the grid connection points i and j.

The second short-circuit ratio index of the renewable energy grid-connected power system is calculated by a formula:

$$SCR - {U}_{i} = \frac{\vert {U}_{N} {\dot{E}}_{eq , i} \vert}{\vert Δ {\dot{U}}_{i} {\dot{U}}_{i} \vert}$$

here SCR-Uᵢ is the second short-circuit ratio index of the renewable energy grid-connected power system; U_{N} is the nominal voltage of the grid connection point i; Ė_{eq,j} is a no-load operation open-circuit voltage of the grid connection point i before the AC system ignores a comprehensive load and the renewable energy is grid-connected; Δ\dot{U}, is the voltage variation of the grid connection point i; and \dot{U}ᵢ is a node voltage of the grid connection point i.

In some embodiments, the operation of determining the CSCR of the renewable energy grid-connected power system based on parameters of the AC system and the equivalent maximum transmission power transmitted to the AC system by the renewable energy may include the following operations.

A transmission power transmitted to the AC system by the renewable energy is determined, here the transmission power is calculated by a formula:

$${\dot{S}}_{eq , i} = ( {U}_{i} cos {θ}_{i} + {jU}_{i} sin {θ}_{i} ) {( \frac{{U}_{i} cos {θ}_{i} + {jU}_{i} sin {θ}_{i} - {E}_{eq , i}}{{R}_{eq , i} + {jX}_{eq , i}} )}^{*}$$

$$\{ \begin{matrix}{P}_{eq , i} = \frac{{U}_{i}^{2} {R}_{eq , i} - {U}_{i} {E}_{eq , i} {R}_{eq , i} cos {θ}_{i} + {U}_{i} {E}_{eq , i} {X}_{eq , i} sin {θ}_{i}}{{R}_{eq , i}^{2} + {X}_{eq , i}^{2}} \\ {Q}_{eq , i} = \frac{{U}_{i}^{2} {X}_{eq , i} - {U}_{i} {E}_{eq , i} {X}_{eq , i} cos {θ}_{i} + {U}_{i} {E}_{eq , i} {X}_{eq , i} sin {θ}_{i}}{{R}_{eq , i}^{2} + {X}_{eq , i}^{2}}\end{matrix}$$

here \dot{S}_{eq,j} is an equivalent grid connection capacity of the renewable energy at a grid connection point i; P_{eq,i}, Q_{eq,i} are an equivalent active power and an equivalent reactive power transmitted to the AC system by the renewable energy respectively; E_{eq,i} is an equivalent potential of the AC system; R_{eq,i} is a Thevenin equivalent resistance of the AC system, and X_{eq,i} is a Thevenin equivalent reactance of the AC system; Uᵢ is a bus voltage of grid connection of the renewable energy; θᵢ is a difference between a phase angle of the bus voltage and a phase angle of the equivalent potential; and j is an imaginary number.

A one-variable quadratic equation about Uᵢ² is established according to a trigonometric function sin² θᵢ+cos² θᵢ=1:

$${U}_{i}^{4} - [ 2 ( {P}_{eq , i} {R}_{eq , i} + {Q}_{eq , i} {X}_{eq , i} ) + {E}_{eq , i}^{2} ] {U}_{i}^{2} + ( {R}_{eq , i}^{2} + {X}_{eq , i}^{2} ) ( {P}_{eq , i}^{2} + {Q}_{eq , i}^{2} ) = 0$$

$$\{ \begin{matrix}λ = \frac{{R}_{eq , i} {P}_{eq , i} + {X}_{eq , i} {Q}_{eq , i}}{{E}_{eq , i}^{2}} \\ μ = \frac{{X}_{eq , i} {P}_{eq , i} - {R}_{eq , i} {Q}_{eq , i}}{{E}_{eq , i}^{2}}\end{matrix}$$

$$Δ = 1 + 4 ( λ - {μ}^{2} ) = 0$$

here λ, μ are sensitivity factors, and Δ is a discriminant of the equation.

The transmission power transmitted to the AC system by the renewable energy is set to be the equivalent maximum transmission power when Δ=0, here the equivalent maximum transmission power is calculated by a formula:

$${P}_{eq , i max} = \frac{\begin{matrix}{R}_{eq , i} ( {E}_{eq , i}^{2} + 2 {Q}_{eq , i} {X}_{eq , i} ) + \\ {E}_{eq , i} \sqrt{{R}_{eq , i}^{2} + {X}_{eq , i}^{2}} \sqrt{{E}_{eq , i}^{2} + 4 {Q}_{eq , i} {X}_{eq , i}}\end{matrix}}{2 {X}_{eq , i}^{2}}$$

here P_{eq,imax} is the equivalent maximum transmission power transmitted to the AC system by the renewable energy, Q_{eq,i} is the equivalent reactive power transmitted to the AC system by the renewable energy, E_{eq,i} is the equivalent potential of the AC system; R_{eq,i} is the Thevenin equivalent resistance of the AC system, and X_{eq,i} is the Thevenin equivalent reactance of the AC system.

The CSCR of the renewable energy grid-connected power system is determined, by:

$$CSCR = \frac{{\dot{S}}_{a c , i}}{\vert {P}_{eq , j ma x} + {jQ}_{eq , i} \vert}$$

here \dot{S}_{ae,j} is a short-circuit capacity provided for the grid connection point i by the AC system; Q_{eq,i} is the equivalent reactive power transmitted to the AC system by the renewable energy; P_{eq,imax} is the equivalent maximum transmission power transmitted to the AC system by the renewable energy; and j is the imaginary number.

In some embodiments, the operation of determining the voltage support strength provided by the renewable energy grid-connected power system at the grid connection point based on the first short-circuit ratio index, the second short-circuit ratio index and the CSCR and by using the preset voltage support strength estimation rule may include the following operations.

An extreme value of the CSCR of the renewable energy grid-connected power system is determined when active power and reactive power of the renewable energy grid-connected power system flow from the renewable energy into the AC system.

The extreme value of the CSCR is determined as a standard for dividing strong and weak voltage support levels of the renewable energy grid-connected power system.

The strong voltage support level of the renewable energy grid-connected power system is determined when the first short-circuit ratio index or the second short-circuit ratio index is greater than the extreme value of the CSCR.

The weak voltage support level of the renewable energy grid-connected power system is determined when the first short-circuit ratio index or the second short-circuit ratio index is less than the extreme value of the CSCR.

In some embodiments, the method may further include the following operations. A stable state of the renewable energy grid-connected power system is determined based on the first short-circuit ratio index, the second short-circuit ratio index and the CSCR.

In some embodiments, the operation of determining the stable state of the renewable energy grid-connected power system based on the first short-circuit ratio index, the second short-circuit ratio index and the CSCR may include the following operations.

It is determined that the renewable energy grid-connected power system operates in a stable region of P-V characteristics and the renewable energy grid-connected power system is in a stable state, when the first short-circuit ratio index or the second short-circuit ratio index is greater than the CSCR.

It is determined that the renewable energy grid-connected power system operates in an unstable region of the P-V characteristics and the renewable energy grid-connected power system is in an unstable state, when the first short-circuit ratio index or the second short-circuit ratio index is less than the CSCR.

According to another aspect of the disclosure, there is provided a system for estimating a voltage support strength of a renewable energy grid-connected power system, including a first short-circuit ratio index determination module, a second short-circuit ratio index determination module, a CSCR determination module, and a voltage support strength determination module.

The first short-circuit ratio index determination module is configured to determine a first short-circuit ratio index of the renewable energy grid-connected power system based on a short-circuit capacity provided for a grid connection point by an AC system in the renewable energy grid-connected power system and an equivalent grid connection capacity of a renewable energy at the grid connection point.

The second short-circuit ratio index determination module is configured to determine a second short-circuit ratio index of the renewable energy grid-connected power system based on a voltage variation at a position where the renewable energy is connected to the grid connection point.

The CSCR determination module is configured to determine a CSCR of the renewable energy grid-connected power system based on parameters of the AC system and an equivalent maximum transmission power transmitted to the AC system by the renewable energy.

The voltage support strength determination module is configured to determine a voltage support strength provided by the renewable energy grid-connected power system at the grid connection point based on the first short-circuit ratio index, the second short-circuit ratio index and the CSCR and by using a preset voltage support strength estimation rule.

In some embodiments, the first short-circuit ratio index determination module may be specifically configured to:
determine the short-circuit capacity provided for the grid connection point by the AC system in the renewable energy grid-connected power system;
determine the equivalent grid connection capacity of the renewable energy at the grid connection point; and
determine the first short-circuit ratio index of the renewable energy grid-connected power system based on the short-circuit capacity and the equivalent grid connection capacity.

In some embodiments, the second short-circuit ratio index determination module may be specifically configured to:
determine a voltage order-reduction equation of the grid connection point when the renewable energy is connected to the grid connection point;
determine the voltage variation at the position where the renewable energy is connected to the grid connection point based on the voltage order-reduction equation;
determine a nominal voltage of the grid connection point; and
determine the second short-circuit ratio index of the renewable energy grid-connected power system based on the voltage variation and the nominal voltage.

In some embodiments, the CSCR determination module may be specifically configured to:
determine a transmission power transmitted to the AC system by the renewable energy, here the transmission power is calculated by a formula:

$${\dot{S}}_{eq , i} = ( {U}_{i} cos {θ}_{i} + {jU}_{i} sin {θ}_{i} ) ( \frac{{U}_{i} cos {θ}_{i} + {jU}_{i} sin {θ}_{i} - {E}_{eq , i}}{{R}_{eq , i} + {jX}_{eq , i}} ) .$$

$$\{ \begin{matrix}{P}_{eq , i} = \frac{{U}_{i}^{2} {R}_{eq , i} - {U}_{i} {E}_{eq , i} {R}_{eq , i} cos {θ}_{i} + {U}_{i} {E}_{eq , i} {X}_{eq , i} sin {θ}_{i}}{{R}_{eq}^{2} + {X}_{eq , i}^{2}} \\ {Q}_{eq , i} = \frac{{U}_{i}^{2} {X}_{eq , i} - {U}_{i} {E}_{eq , i} {X}_{eq , i} cos {θ}_{i} - {U}_{i} {E}_{eq , i} {R}_{eq , i} sin {θ}_{i}}{{R}_{eq , i}^{2} + {X}_{eq , i}^{2}}\end{matrix}$$

here \dot{S}_{eq,j} is an equivalent grid connection capacity of the renewable energy at a grid connection point i; P_{eq,i}, Q_{eq,i} are an equivalent active power and an equivalent reactive power transmitted to the AC system by the renewable energy respectively; E_{eq,i} is an equivalent potential of the AC system; R_{eq,i} is a Thevenin equivalent resistance of the AC system, and X_{eq,i} is a Thevenin equivalent reactance of the AC system; Uᵢ is a bus voltage of grid connection of the renewable energy; θᵢ is a difference between a phase angle of the bus voltage and a phase angle of the equivalent potential; and j is an imaginary number,
establish a one-variable quadratic equation about Uᵢ² according to a trigonometric function sin² θᵢ+cos² θᵢ=1:

$${U}_{i}^{4} - [ 2 ( {P}_{eq , i} {R}_{eq , i} + {Q}_{eq , i} {X}_{cq , i} ) + {E}_{eq , i}^{2} ] {U}_{i}^{2} + ( {R}_{eq , i}^{2} + {X}_{eq , i}^{2} ) ( {P}_{eq , i}^{2} + {Q}_{eq , i}^{2} ) = 0$$

$$\{ \begin{matrix}λ = \frac{{R}_{eq , i} {P}_{eq , j} + {X}_{eq , i} {Q}_{eq , i}}{{E}_{eq , i}^{2}} \\ μ = \frac{{X}_{eq , j} {P}_{eq , j} - {R}_{eq , j} {Q}_{eq , j}}{{E}_{eq , i}^{2}}\end{matrix}$$

$$Δ = 1 + 4 ( λ - {u}^{2} ) = 0$$

here λ, μ are sensitivity factors, and Δ is a discriminant of the equation;
set the transmission power transmitted to the AC system by the renewable energy to be the equivalent maximum transmission power when Δ=0, here the equivalent maximum transmission power is calculated by a formula:

$${P}_{eq , i ma x} = \frac{{R}_{eq , i} ( {E}_{eq , i}^{2} + 2 {Q}_{eq , i} {X}_{eq , i} ) + {E}_{eq , i} \sqrt{{R}_{eq , i}^{2} + {X}_{eq , i}^{2}} \sqrt{{E}_{eq , i}^{2} + 4 {Q}_{eq , i} {X}_{eq , i}}}{2 {X}_{cq , i}^{2}}$$

here P_{eq,imax} is the equivalent maximum transmission power transmitted to the AC system by the renewable energy, Q_{eq,i} is the equivalent reactive power transmitted to the AC system by the renewable energy, E_{eq,i} is the equivalent potential of the AC system; R_{eq,i} is the Thevenin equivalent resistance of the AC system, and X_{eq,i} is the Thevenin equivalent reactance of the AC system; and
determine the CSCR of the renewable energy grid-connected power system, by:

$$CSCR = \frac{{\dot{S}}_{a c , i}}{\vert {P}_{eq , j ma x} + {jQ}_{eq , j} \vert}$$

here \dot{S}_{ac,i} is a short-circuit capacity provided for the grid connection point i by the AC system; Q_{eq,i} is the equivalent reactive power transmitted to the AC system by the renewable energy; P_{eq,imax} is the equivalent maximum transmission power transmitted to the AC system by the renewable energy; and j is the imaginary number.

In some embodiments, the voltage support strength determination module may be specifically configured to:
determine an extreme value of the CSCR of the renewable energy grid-connected power system when active power and reactive power of the renewable energy grid-connected power system flow from the renewable energy into the AC system;
determine the extreme value of the CSCR as a standard for dividing strong and weak voltage support levels of the renewable energy grid-connected power system;
determine the strong voltage support level of the renewable energy grid-connected power system when the first short-circuit ratio index or the second short-circuit ratio index is greater than the extreme value of the CSCR; and
determine the weak voltage support level of the renewable energy grid-connected power system when the first short-circuit ratio index or the second short-circuit ratio index is less than the extreme value of the CSCR.

According to yet another aspect of the disclosure, there is provided a computer-readable storage medium, having stored thereon a computer program, the computer program executes the method of any one of the above aspects of the disclosure.

According to yet another aspect of the disclosure, there is provided an electronic device, including a processor and a memory. The memory is configured to store an executable instruction of the processor. The processor is configured to read the executable instruction from the memory and execute the instruction to implement the method of any one of the above aspects of the disclosure.

Therefore, according to the disclosure, firstly, the first short-circuit ratio index of the renewable energy grid-connected power system is determined based on the short-circuit capacity provided for the grid connection point by the AC system in the renewable energy grid-connected power system and the equivalent grid connection capacity of the renewable energy at the grid connection point. Then, the second short-circuit ratio index of the renewable energy grid-connected power system is determined based on the voltage variation at the position where the renewable energy is connected to the grid connection point. Secondly, the CSCR of the renewable energy grid-connected power system is determined based on parameters of the AC system and the equivalent maximum transmission power transmitted to the AC system by the renewable energy. Finally, the voltage support strength provided by the renewable energy grid-connected power system at the grid connection point is determined based on the first short-circuit ratio index, the second short-circuit ratio index and the CSCR and by using the preset voltage support strength estimation rule. The disclosure proposes a practical method for calculating the CSCR, by constructing accurate and practical short-circuit ratio indexes, and provides an accurate, rapid, intuitive and practical method and system for estimating the voltage support strength of the renewable energy grid-connected power system, by taking the CSCR as a reference point and taking the short-circuit ratio of the system as a coordinate. Therefore, the disclosure may estimate the voltage support strength of the renewable energy grid-connected power system more intuitively and simply with characteristics of accuracy and rapidity, and the method is simple and practical, which are of great significance to ensure a safe and stable operation of the renewable energy grid-connected power system.

### BRIEF DESCRIPTION OF THE DRAWINGS

Exemplary implementations of the disclosure may be understood more completely with reference to the following drawings:

FIG. 1 is a schematic flowchart of a method for estimating a voltage support strength of a renewable energy grid-connected power system according to an exemplary embodiment of the disclosure;

FIG. 2 is a schematic diagram of an association relationship among a stable state and strong and weak levels of a renewable energy grid-connected power system, a first short-circuit ratio index, a second short-circuit ratio index and a CSCR according to an exemplary embodiment of the disclosure;

FIG. 3 is a schematic structural diagram of a system for estimating a voltage support strength of a renewable energy grid-connected power system according to an exemplary embodiment of the disclosure; and

FIG. 4 is a schematic structural diagram of an electronic device according to an exemplary embodiment of the disclosure.

### DETAILED DESCRIPTION

Exemplary embodiments of the disclosure will be described in detail below with reference to the drawings. It is apparent that the described embodiments are only part of the embodiments of the disclosure, rather than all of the embodiments of the disclosure. It should be understood that the disclosure is not limited by the exemplary embodiments described here.

It should be noted that relative arrangements, numeric expressions and values of components and operations described in these embodiments do not limit the scope of the disclosure, unless otherwise specified.

It may be understood by those skilled in the art that terms “first”, “second” or the like in embodiments of the disclosure are only intended to distinguish different operations, devices, modules, etc., do not represent any particular technical meaning, and do not represent necessary logical orders among the operations, devices, modules, etc.

It should also be understood that in the embodiments of the disclosure, “multiple” may mean two or more, and “at least one” may mean one, two or more.

It should also be understood that any component, data or structure mentioned in the embodiments of the disclosure may be generally understood as one or more component, data or structure, without clear limitations or contrary inspirations given in the context.

Furthermore, a term “and/or” in the disclosure is only an association relationship describing associated objects, and indicates that there may be three relationships. For example, A and/or B may indicate three cases: existence of A alone, existence of A and B simultaneously, and existence of B alone. Furthermore, a character “/” in the disclosure generally indicates that associated objects are in an “or” relationship.

It should also be understood that descriptions of the embodiments of the disclosure emphasize differences among the embodiments, and the same or similar contents of the embodiments may refer to each other and are not elaborated in detail for sake of brevity.

Furthermore, it should be understood that for convenience of descriptions, dimensions of parts shown in the drawings are not drawn according to actual proportional relationships thereof.

Following descriptions of at least one exemplary embodiment are actually only illustrative and do not constitute any limitation on the disclosure and application or usage thereof.

Technologies, methods and devices known to those of ordinary skill in the relevant art may not be discussed in detail, however, the technologies, methods and devices should be considered as part of the specification in an appropriate case.

It should be noted that similar reference symbols and letters represent similar items in the following drawings. Therefore, once an item is defined in one drawing, it does not need to be further discussed in subsequent drawings.

The embodiments of the disclosure may be applied to electronic devices such as terminal devices, computer systems, servers, etc., which may operate with multiple other general-purpose or special-purpose computing systems, environments or configurations. Examples of well-known terminal devices, computing systems, environments and/or configurations suitable to use with the electronic devices such as terminal devices, computer systems, servers, etc. include but are not limited to: personal computer systems, server computer systems, thin clients, thick clients, hand-held or laptop devices, microprocessor-based systems, set-top boxes, programmable consumer electronics, networked personal computers, minicomputer systems, mainframe computer systems, distributed cloud computing technology environments including any of the above systems, etc.

The electronic devices such as terminal devices, computer systems, servers, etc. may be described in a general context of computer system executable instructions (such as program modules) executed by a computer system. Generally, the program modules may include routines, programs, object programs, components, logics, data structures, etc., which perform specific tasks or implement specific types of abstract data. The computer systems/servers may be implemented in a distributed cloud computing environment where tasks are performed by remote processing devices linked through a communication network. In the distributed cloud computing environment, program modules may be located on a storage medium of a local or remote computing system which includes a storage device.

### Exemplary Method

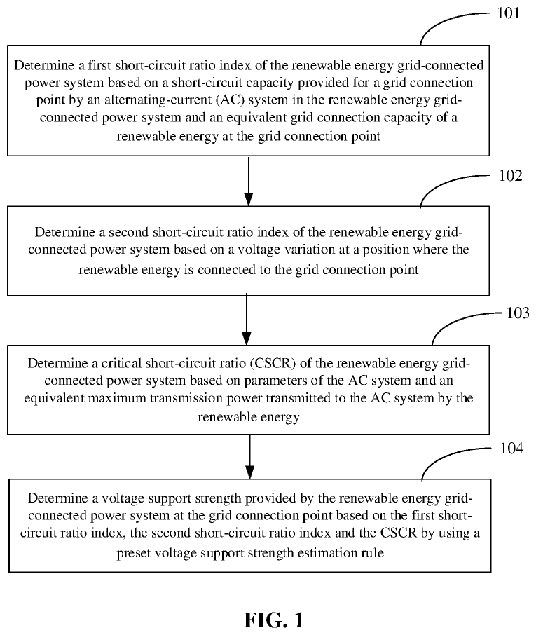

FIG. 1 is a schematic flowchart of a method for estimating a voltage support strength of a renewable energy grid-connected power system according to an exemplary embodiment of the disclosure. The embodiment may be applied to an electronic device. As shown in FIG. 1, the method for estimating a voltage support strength of a renewable energy grid-connected power system includes the following operations 101 to 104.

At 101, a first short-circuit ratio index of the renewable energy grid-connected power system is determined based on a short-circuit capacity provided for a grid connection point by an alternating-current (AC) system in the renewable energy grid-connected power system and an equivalent grid connection capacity of a renewable energy at the grid connection point.

In the embodiment of the disclosure, with respect to the renewable energy grid-connected power system, calculating the first short-circuit ratio index SCR-S of the renewable energy grid-connected power system based on capacities is proposed according to a concept of short-circuit ratio and by adopting a ratio of the short-circuit capacity of the AC system to the equivalent grid connection capacity.

In some embodiments, the operation 101 includes the following operations 101a to 101c.

At 101a, the short-circuit capacity provided for the grid connection point by the AC system in the renewable energy grid-connected power system is determined.

In some embodiments, the short-circuit capacity provided for the grid connection point by the AC system is calculated by a formula:

$${\dot{S}}_{a c , i} = \frac{{U}_{N} {\dot{E}}_{eq , i}}{{\dot{Z}}_{ii}}$$

here Ė_{ac,i} is a no-load operation open-circuit voltage of a grid connection point i before the AC system ignores a comprehensive load and the renewable energy is grid-connected; Żᵢᵢ is a diagonal element in an impedance matrix of the grid connection point, which is an equivalent impedance of the AC system to the grid connection point i; and U_{N} is a nominal voltage of the grid connection point i.

At 101b, the equivalent grid connection capacity of the renewable energy at the grid connection point is determined.

In some embodiments, the equivalent grid connection capacity of the renewable energy at the grid connection point is calculated by a formula:

$${\dot{S}}_{eq , i} = {\dot{U}}_{i} {I}_{eq , j}^{*} = {\dot{S}}_{i} + {\sum }_{j \neq i} \frac{{\dot{Z}}_{ij}^{*}}{{\dot{Z}}_{ii}^{*}} \frac{{\dot{U}}_{i}}{{\dot{U}}_{j}} {\dot{S}}_{j}$$

here * represents a conjugate operation; \dot{S}ᵢ, \dot{S}ⱼ, are capacities of renewable energies directly connected to grid connection points i and j; I_{eq,i} is a line current; Żᵢⱼ is a non-diagonal element in an impedance matrix of the grid connection point, which reflects an electrical distance between the grid connection points i and j; Żᵢᵢ is a diagonal element in the impedance matrix of the grid connection point, which is an equivalent impedance of the AC system to the grid connection point i; and \dot{U}ᵢ, \dot{U}ⱼ are node voltages of the grid connection points i and j.

At 101c, the first short-circuit ratio index of the renewable energy grid-connected power system is determined based on the short-circuit capacity and the equivalent grid connection capacity.

In some embodiments, the first short-circuit ratio index of the renewable energy grid-connected power system is calculated by a formula:

$$SCR ‐ {S}_{i} = \frac{{\dot{S}}_{a c , i}}{{\dot{S}}_{eq , i}} = \frac{\vert {U}_{N} {\dot{E}}_{eq , j} / {\dot{Z}}_{ii} \vert}{\vert {\dot{S}}_{i} + {\sum }_{j \neq i} \frac{{\dot{Z}}_{ij}^{*}}{{\dot{Z}}_{ii}^{*}} \frac{{\dot{U}}_{l}}{{\dot{U}}_{j}} {\dot{S}}_{j} \vert}$$

here SCR-S; is the first short-circuit ratio index of the renewable energy grid-connected power system; \dot{S}_{ac,i} is a short-circuit capacity provided for a grid connection point i by the AC system; \dot{S}_{eq,i} is an equivalent grid connection capacity of the renewable energy at the grid connection point i; \dot{U}ᵢ, \dot{U}ⱼ are node voltages of grid connection points i and j; U_{N} is a nominal voltage of the grid connection point i; Ė_{eq,i} is a no-load operation open-circuit voltage of the grid connection point i before the AC system ignores a comprehensive load and the renewable energy is grid-connected; Żᵢᵢ is a diagonal element in an impedance matrix of the grid connection point, which is an equivalent impedance of the AC system to the grid connection point i; Żᵢⱼ is a non-diagonal element in the impedance matrix of the grid connection point, which reflects an electrical distance between the grid connection points i and j; and \dot{S}ᵢ, \dot{S}ᵢ are capacities of renewable energies directly connected to the grid connection points i and j.

At 102, a second short-circuit ratio index of the renewable energy grid-connected power system is determined based on a voltage variation at a position where the renewable energy is connected to the grid connection point.

In some embodiments, the operation 102 includes the following operations 102a to 102d.

At 102a, a voltage order-reduction equation of the grid connection point is determined when the renewable energy is connected to the grid connection point.

In some embodiments, the voltage order-reduction equation of the grid connection point is:

$$[ \begin{matrix}Δ {\dot{U}}_{1} \\ ⋮ \\ Δ {\dot{U}}_{i} \\ ⋮ \\ Δ {\dot{U}}_{m}\end{matrix} ] = [ \begin{matrix}{\dot{Z}}_{11} & ⋯ & {\dot{Z}}_{1 i} & ⋯ & {\dot{Z}}_{1 m} \\ ⋮ & & ⋮ & & ⋮ \\ {\dot{Z}}_{i 1} & ⋯ & {\dot{Z}}_{ii} & ⋯ & {\dot{Z}}_{im} \\ ⋮ & & ⋮ & & ⋮ \\ {\dot{Z}}_{m 1} & ⋯ & {\dot{Z}}_{m i} & ⋯ & {\dot{Z}}_{m m}\end{matrix} ] [ \begin{matrix}{\dot{I}}_{E , 1} \\ ⋮ \\ {\dot{I}}_{E , i} \\ ⋮ \\ {\dot{I}}_{E , m}\end{matrix} ]$$

here Ż is an impedance matrix of the grid connection point; A\dot{U} is a voltage variation at the grid connection point caused when the renewable energy is grid-connected; İ_{E} is a current injected by the renewable energy; and m is a serial number of the grid connection point.

At 102b, the voltage variation at the position where the renewable energy is connected to the grid connection point, is determined based on the voltage order-reduction equation.

In some embodiments, the voltage variation at the position where the renewable energy is connected to the grid connection point is calculated by a formula:

$$Δ {\dot{U}}_{i} = {\dot{Z}}_{ii} {\dot{I}}_{E , j} + {\sum }_{j \neq i} {\dot{Z}}_{ij} {\dot{I}}_{E , j}$$

here Δ\dot{U}ᵢ is a voltage variation of the grid connection point i; İ_{E,i}, İ_{E,j} are currents injected by the renewable energy into grid connection points i, j; Żᵢᵢ is a diagonal element in an impedance matrix of the grid connection point, which is an equivalent impedance of the ac system to the grid connection point i; and Żᵢⱼ is a non-diagonal element in the impedance matrix of the grid connection point, which reflects an electrical distance between the grid connection points i and j.

At 102c, a nominal voltage U_{N} of the grid connection point is determined.

At 102d, the second short-circuit ratio index of the renewable energy grid-connected power system is determined based on the voltage variation and the nominal voltage.

In the embodiment of the disclosure, at 102d, a formula of calculating a ratio of the nominal voltage to the voltage variation is determined first.

Here the ratio of the nominal voltage to the voltage variation is calculated by a [00130] formula:

$$\frac{\vert {U}_{N} \vert}{\vert Δ {\dot{U}}_{i} \vert} = \frac{\vert {U}_{N} \vert}{\vert {\dot{Z}}_{ii} {\dot{I}}_{E , j} + {\sum }_{{j}^{′} i} {\dot{Z}}_{ij} {\dot{I}}_{E , j} \vert}$$

here U_{N} is a nominal voltage of the grid connection point i; Δ\dot{U}ᵢ is the voltage variation of the grid connection point i; İ_{E,j}, İ_{E,i} are the currents injected by the renewable energy into the grid connection points i, j; Żᵢᵢ is the diagonal element in the impedance matrix of the grid connection point, which is the equivalent impedance of the AC system to the grid connection point i; and Żᵢⱼ is the non-diagonal element in the impedance matrix of the grid connection point, which reflects the electrical distance between the grid connection points i and j.

Then, the formula of calculating the ratio of the nominal voltage to the voltage variation is further derived, and the second short-circuit ratio index of the renewable energy grid-connected power system is determined. Here the second short-circuit ratio index of the renewable energy grid-connected power system is calculated by a formula:

$$SCR ‐ {U}_{i} = \frac{\vert {U}_{N} {\dot{E}}_{eq , i} \vert}{\vert Δ {\dot{U}}_{i} {\dot{U}}_{i} \vert}$$

here SCR-Uᵢ is the second short-circuit ratio index of the renewable energy grid-connected power system; U_{N} is the nominal voltage of the grid connection point i; Ė_{eq,j} is a no-load operation open-circuit voltage of the grid connection point i before the AC system ignores a comprehensive load and the renewable energy is grid-connected; Δ\dot{U}ᵢ is the voltage variation of the grid connection point i; and \dot{U}ᵢ is a node voltage of the grid connection point i.

At 103, a critical short-circuit ratio (CSCR) of the renewable energy grid-connected power system is determined based on parameters of the AC system and an equivalent maximum transmission power transmitted to the AC system by the renewable energy.

In some embodiments, the operation 103 includes the following operations 103a to 103d.

At 103a, a transmission power transmitted to the AC system by the renewable energy is determined, here the transmission power is calculated by a formula:

$${\dot{S}}_{eq , i} = ( {U}_{i} cos {θ}_{i} + {jU}_{i} sin {θ}_{i} ) ( \frac{{U}_{i} cos {θ}_{i} + {jU}_{i} sin {θ}_{i} - {E}_{eq , i}}{{R}_{eq , i} + {jX}_{eq , i}} ) .$$

$$\{ \begin{matrix}{P}_{eq , i} = \frac{{U}_{i}^{2} {R}_{eq , i} - {U}_{i} {E}_{eq , i} {R}_{eq , i} cos {θ}_{i} + {U}_{i} {E}_{eq , i} {X}_{eq , i} sin {θ}_{i}}{{R}_{eq}^{2} + {X}_{eq , i}^{2}} \\ {Q}_{eq , i} = \frac{{U}_{i}^{2} {X}_{eq , i} - {U}_{i} {E}_{eq , i} {X}_{eq , i} cos {θ}_{i} - {U}_{i} {E}_{eq , i} {R}_{eq , i} sin {θ}_{i}}{{R}_{eq , i}^{2} + {X}_{eq , i}^{2}}\end{matrix}$$

here \dot{S}_{eq,i} is an equivalent grid connection capacity of the renewable energy at a grid connection point i; P_{eq,i}, Q_{eq,i} are an equivalent active power and an equivalent reactive power transmitted to the AC system by the renewable energy respectively; E_{eq,i} is an equivalent potential of the AC system; R_{eq,i} is a Thevenin equivalent resistance of the AC system, and X_{eq,i} is a Thevenin equivalent reactance of the AC system; Uᵢ is a bus voltage of grid connection of the renewable energy; θᵢ is a difference between a phase angle of the bus voltage and a phase angle of the equivalent potential; and j is an imaginary number.

At 103b, a one-variable quadratic equation about Uᵢ² is established according to a trigonometric function sin² θᵢ+cos² θᵢ=1:

$${U}_{i}^{4} - [ 2 ( {P}_{eq , i} {R}_{eq , i} + {Q}_{eq , i} {X}_{cq , i} ) + {E}_{eq , i}^{2} ] {U}_{i}^{2} + ( {R}_{eq , i}^{2} + {X}_{eq , i}^{2} ) ( {P}_{eq , i}^{2} + {Q}_{eq , i}^{2} ) = 0$$

$$\{ \begin{matrix}λ = \frac{{R}_{eq , i} {P}_{eq , i} + {X}_{eq , i} {Q}_{eq , i}}{{E}_{eq , i}^{2}} \\ μ = \frac{{X}_{eq , i} {P}_{eq , i} - {R}_{eq , i} {Q}_{eq , i}}{{E}_{eq , i}^{2}}\end{matrix}$$

$$Δ = 1 + 4 ( λ - {μ}^{2} ) = 0$$

here λ, μ are sensitivity factors, and Δ is a discriminant of the equation.

At 103c, the transmission power transmitted to the AC system by the renewable energy is set to be the equivalent maximum transmission power when Δ=0, here the equivalent maximum transmission power is calculated by a formula:

$${P}_{eq . i ma x} = \frac{{R}_{eq , i} ( {E}_{eq , i}^{2} + 2 {Q}_{eq , i} {X}_{eq , i} ) + {E}_{eq , i} \sqrt{{R}_{eq , i}^{2} + {X}_{eq , i}^{2}} \sqrt{{E}_{eq , i}^{2} + 4 {Q}_{eq , i} {X}_{eq , i}}}{2 {X}_{eq , i}^{2}}$$

here P_{eq,imax} is the equivalent maximum transmission power transmitted to the AC system by the renewable energy, Q_{eq,i} is the equivalent reactive power transmitted to the AC system by the renewable energy, E_{eq,i} is the equivalent potential of the AC system; R_{eq,i} is the Thevenin equivalent resistance of the AC system, and X_{eq,i} is the Thevenin equivalent reactance of the AC system.

At 103d, the CSCR of the renewable energy grid-connected power system is determined, by:

$$CSCR = \frac{{\dot{S}}_{a c , i}}{\vert {P}_{eq , ima x} + {jQ}_{eq , i} \vert}$$

here \dot{S}_{ac,i} is a short-circuit capacity provided for the grid connection point i by the AC system; Q_{eq,i} is the equivalent reactive power transmitted to the AC system by the renewable energy; P_{eq,imax} is the equivalent maximum transmission power transmitted to the AC system by the renewable energy; and j is the imaginary number.

In the embodiment of the disclosure, the parameters of the AC system include the equivalent potential E_{eq,i} of the AC system, the Thevenin equivalent resistance R_{eq,i} of the AC system, and the Thevenin equivalent reactance X_{eq,i} of the AC system.

At 104, a voltage support strength provided by the renewable energy grid-connected power system at the grid connection point is determined based on the first short-circuit ratio index, the second short-circuit ratio index and the CSCR and by using a preset voltage support strength estimation rule.

In the embodiment of the disclosure, the preset voltage support strength estimation rule is as follows:
1) It is determined that an abstract concept of the voltage support strength of the renewable energy grid-connected power system exists with reference to a standard for dividing strong and weak levels of the renewable energy grid-connected power system, estimation of the voltage support strength of the renewable energy grid-connected power system is implemented by taking the CSCR of grid connection of the renewable energy as a reference point and taking the short-circuit ratio index of grid connection of the renewable energy as a coordinate.
2) It is determined that two short-circuit ratio indexes with the same estimation effect are constructed for the renewable energy grid-connected power system: SCR-S (corresponding to the first short-circuit ratio index) and SCR-U (corresponding to the second short-circuit ratio index).
3) It is determined that a stable state of the renewable energy grid-connected power system is determined by comparing the short-circuit ratio indexes of the renewable energy grid-connected power system with the CSCR. When the renewable energy grid-connected power system does not reach a critical stability, there is a distance between the short-circuit ratio index and the CSCR, and the renewable energy grid-connected power system has a safety margin. That is:
3.1) when SCR-U (or SCR-S) is greater than the CSCR (corresponding to the critical short-circuit ratio), the renewable energy grid-connected power system operates in a stable region of P-V characteristics and the renewable energy grid-connected power system is in a stable state;
3.2) when SCR-U (or SCR-S) is less than the CSCR (corresponding to the critical short-circuit ratio), the renewable energy grid-connected power system operates in an unstable region of the P-V characteristics and the renewable energy grid-connected power system is in an unstable state.
4) It is determined that strong and weak levels of the renewable energy grid-connected power system is determined by calculating the short-circuit ratio indexes of the renewable energy grid-connected power system and comparing the short-circuit ratio indexes with the standard for dividing strong and weak levels of the renewable energy grid-connected power system. Here strong level of the renewable energy grid-connected power system means a strong voltage support level provided by the renewable energy grid-connected power system at the grid connection point, and weak level of the renewable energy grid-connected power system means a weak voltage support level provided by the renewable energy grid-connected power system at the grid connection point.
4.1) When the short-circuit ratio index (SCR-U or SCR-S) is greater than 2, the renewable energy grid-connected power system is a strong system;
4.2) When the short-circuit ratio index (SCR-U or SCR-S) is less than 2, the renewable energy grid-connected power system is a weak system.

In some embodiments, the operation 104 includes the following operations 104a to 104d.

At 104a, an extreme value of the CSCR of the renewable energy grid-connected power system is determined when active power and reactive power of the renewable energy grid-connected power system flow from the renewable energy into the AC system.

In the embodiment of the disclosure, it may be known by referring to the formula of calculating the CSCR of the renewable energy grid-connected power system that when the active power and reactive power of the renewable energy grid-connected power system flow from the renewable energy into the AC system, the CSCR of the renewable energy grid-connected power system has a maximum value of 2 (corresponding to the extreme value).

At 104b, the extreme value of the CSCR is determined as a standard for dividing strong and weak voltage support levels of the renewable energy grid-connected power system.

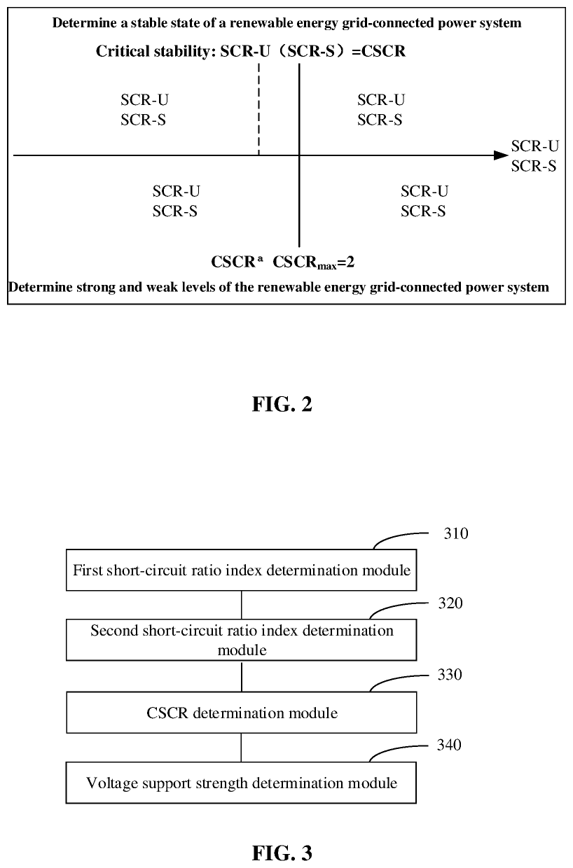

In the embodiment of the disclosure, as shown in FIG. 2, the extreme value of 2 of the CSCR is taken as a standard for dividing strong and weak levels of the renewable energy grid-connected power system. Here strong level of the renewable energy grid-connected power system means a strong voltage support level provided by the renewable energy grid-connected power system at the grid connection point, and weak level of the renewable energy grid-connected power system means a weak voltage support level provided by the renewable energy grid-connected power system at the grid connection point.

At 104c, the strong voltage support level of the renewable energy grid-connected power system is determined when the first short-circuit ratio index or the second short-circuit ratio index is greater than the extreme value of the CSCR.

At 104d, the weak voltage support level of the renewable energy grid-connected power system is determined when the first short-circuit ratio index or the second short-circuit ratio index is less than the extreme value of the CSCR.

In some embodiments, the method further includes the following operations. A stable state of the renewable energy grid-connected power system is determined based on the first short-circuit ratio index, the second short-circuit ratio index and the CSCR.

In some embodiments, as shown in FIG. 2, the operation of determining the stable state of the renewable energy grid-connected power system based on the first short-circuit ratio index, the second short-circuit ratio index and the CSCR includes the following operations.
1) It is determined that the renewable energy grid-connected power system operates in a stable region of P-V characteristics and the renewable energy grid-connected power system is in a stable state, when the first short-circuit ratio index or the second short-circuit ratio index is greater than the CSCR.
2) It is determined that the renewable energy grid-connected power system operates in an unstable region of the P-V characteristics and the renewable energy grid-connected power system is in an unstable state, when the first short-circuit ratio index or the second short-circuit ratio index is less than the CSCR.

Therefore, according to the disclosure, firstly, the first short-circuit ratio index of the renewable energy grid-connected power system is determined based on the short-circuit capacity provided for the grid connection point by the AC system in the renewable energy grid-connected power system and the equivalent grid connection capacity of the renewable energy at the grid connection point. Then, the second short-circuit ratio index of the renewable energy grid-connected power system is determined based on the voltage variation at the position where the renewable energy is connected to the grid connection point. Secondly, the CSCR of the renewable energy grid-connected power system is determined based on parameters of the AC system and the equivalent maximum transmission power transmitted to the AC system by the renewable energy. Finally, the voltage support strength provided by the renewable energy grid-connected power system at the grid connection point is determined based on the first short-circuit ratio index, the second short-circuit ratio index and the CSCR and by using the preset voltage support strength estimation rule. The disclosure proposes a practical method for calculating the CSCR, by constructing accurate and practical short-circuit ratio indexes, and provides an accurate, rapid, intuitive and practical method and system for estimating the voltage support strength of the renewable energy grid-connected power system, by taking the CSCR as a reference point and taking the short-circuit ratio of the system as a coordinate. Therefore, the disclosure may estimate the voltage support strength of the renewable energy grid-connected power system more intuitively and simply with characteristics of accuracy and rapidity, and the method is simple and practical, which are of great significance to ensure a safe and stable operation of the renewable energy grid-connected power system.

### Exemplary System

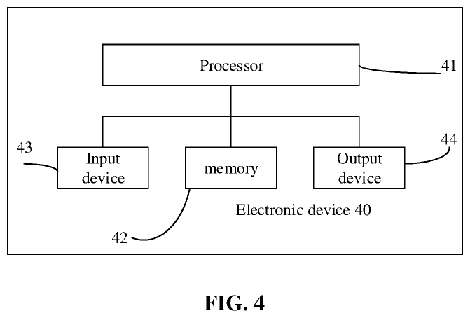

FIG. 3 is a schematic structural diagram of a system for estimating a voltage support strength of a renewable energy grid-connected power system according to an exemplary embodiment of the disclosure. As shown in FIG. 3, the system includes a first short-circuit ratio index determination module 310, a second short-circuit ratio index determination module 320, a CSCR determination module 330, and a voltage support strength determination module 340.

The first short-circuit ratio index determination module 310 is configured to determine a first short-circuit ratio index of the renewable energy grid-connected power system based on a short-circuit capacity provided for a grid connection point by an AC system in the renewable energy grid-connected power system and an equivalent grid connection capacity of a renewable energy at the grid connection point.

The second short-circuit ratio index determination module 320 is configured to determine a second short-circuit ratio index of the renewable energy grid-connected power system based on a voltage variation at a position where the renewable energy is connected to the grid connection point.

The CSCR determination module 330 is configured to determine a CSCR of the renewable energy grid-connected power system based on parameters of the AC system and an equivalent maximum transmission power transmitted to the AC system by the renewable energy.

The voltage support strength determination module 340 is configured to determine a voltage support strength provided by the renewable energy grid-connected power system at the grid connection point based on the first short-circuit ratio index, the second short-circuit ratio index and the CSCR and by using a preset voltage support strength estimation rule.

In some embodiments, the first short-circuit ratio index determination module 310 is specifically configured to:
determine the short-circuit capacity provided for the grid connection point by the AC system in the renewable energy grid-connected power system;
determine the equivalent grid connection capacity of the renewable energy at the grid connection point; and
determine the first short-circuit ratio index of the renewable energy grid-connected power system based on the short-circuit capacity and the equivalent grid connection capacity.

In some embodiments, the short-circuit capacity provided for the grid connection point by the AC system is calculated by a formula:

$${\dot{S}}_{a c , i} = \frac{{U}_{N} {\dot{E}}_{eq , i}}{{\dot{Z}}_{ii}}$$

here Ė_{eq,i} is a no-load operation open-circuit voltage of a grid connection point i before the AC system ignores a comprehensive load and the renewable energy is grid-connected; Żᵢᵢ is a diagonal element in an impedance matrix of the grid connection point, which is an equivalent impedance of the AC system to the grid connection point i; and U_{N} is a nominal voltage of the grid connection point i.

In some embodiments, the equivalent grid connection capacity at the grid connection point is calculated by a formula:

$${\dot{S}}_{eq , i} = {\dot{U}}_{i} {I}_{eq , i}^{*} = {S}_{i}^{*} + {\sum }_{j \neq i} \frac{{\dot{Z}}_{ij}^{*}}{{\dot{Z}}_{ii}^{*}} \frac{{\dot{U}}_{i}}{{\dot{U}}_{j}} {\dot{S}}_{j}$$

here * represents a conjugate operation; \dot{S}ᵢ, \dot{S}ⱼ are capacities of renewable energies directly connected to grid connection points i and j; I_{eq,i} is a line current; Żᵢᵢ is a non-diagonal element in an impedance matrix of the grid connection point, which reflects an electrical distance between the grid connection points i and j; Żᵢⱼ is a diagonal element in the impedance matrix of the grid connection point, which is an equivalent impedance of the AC system to the grid connection point i; and \dot{U}ᵢ, \dot{U}ⱼ are node voltages of the grid connection points i and j.

In some embodiments, the first short-circuit ratio index of the renewable energy grid-connected power system is calculated by a formula:

$$SCR ‐ {S}_{j} = \frac{{\dot{S}}_{a c , j}}{{\dot{S}}_{eq , j}} = \frac{\vert {U}_{N} {\dot{E}}_{eq , j} / {\dot{Z}}_{ii} \vert}{\vert {\dot{S}}_{i} + {\sum }_{j \neq i} \frac{{\dot{Z}}_{ij}^{*}}{{\dot{Z}}_{ii}^{*}} \frac{{\dot{U}}_{i}}{{\dot{U}}_{j}} {\dot{S}}_{j} \vert}$$

here SCR-Sᵢ is the first short-circuit ratio index of the renewable energy grid-connected power system; \dot{S}_{ac,i} is a short-circuit capacity provided for a grid connection point i by the AC system; \dot{S}_{eq,i} is an equivalent grid connection capacity of the renewable energy at the grid connection point i; \dot{U}ᵢ, \dot{U}ⱼ are node voltages of grid connection points i and j; U_{N} is a nominal voltage of the grid connection point i; Ė_{eq,i} is a no-load operation open-circuit voltage of the grid connection point i before the AC system ignores a comprehensive load and the renewable energy is grid-connected; Żᵢᵢ is a diagonal element in an impedance matrix of the grid connection point, which is an equivalent impedance of the AC system to the grid connection point i; Żᵢⱼ is a non-diagonal element in the impedance matrix of the grid connection point, which reflects an electrical distance between the grid connection points i and j; and \dot{S}ᵢ, \dot{S}ⱼ are capacities of renewable energies directly connected to the grid connection points i and j.

In some embodiments, the second short-circuit ratio index determination module 320 is specifically configured to:
determine a voltage order-reduction equation of the grid connection point when the renewable energy is connected to the grid connection point;
determine the voltage variation at the position where the renewable energy is connected to the grid connection point based on the voltage order-reduction equation;
determine a nominal voltage of the grid connection point; and
determine the second short-circuit ratio index of the renewable energy grid-connected power system based on the voltage variation and the nominal voltage.

In some embodiments, the voltage order-reduction equation of the grid connection point is:

$$[ \begin{matrix}Δ {\dot{U}}_{1} \\ ⋮ \\ Δ {\dot{U}}_{i} \\ ⋮ \\ Δ {\dot{U}}_{m}\end{matrix} ] = [ \begin{matrix}{\dot{Z}}_{11} & ⋯ & {\dot{Z}}_{1 i} & ⋯ & {\dot{Z}}_{1 m} \\ ⋮ & & ⋮ & & ⋮ \\ {\dot{Z}}_{i 1} & ⋯ & {\dot{Z}}_{ii} & ⋯ & {\dot{Z}}_{im} \\ ⋮ & & ⋮ & & ⋮ \\ {\dot{Z}}_{m 1} & ⋯ & {\dot{Z}}_{m i} & ⋯ & {\dot{Z}}_{m m}\end{matrix} ] [ \begin{matrix}{\dot{I}}_{E , 1} \\ ⋮ \\ {\dot{I}}_{E , i} \\ ⋮ \\ {\dot{I}}_{E , m}\end{matrix} ]$$

here Ż is an impedance matrix of the grid connection point; Δ\dot{U} is a voltage variation at the grid connection point caused when the renewable energy is grid-connected; İ_{E} is a current injected by the renewable energy; and m is a serial number of the grid connection point.

In some embodiments, the voltage variation at the position where the renewable energy is connected to the grid connection point is calculated by a formula:

$$Δ {\dot{U}}_{i} = {\dot{Z}}_{u} {\dot{I}}_{E , i} + {\sum }_{j \neq i} {\dot{Z}}_{ij} {\dot{I}}_{E , j}$$

here Δ\dot{U}ᵢ is a voltage variation of the grid connection point i; İ_{E,j}, İ_{E,i} are currents injected by the renewable energy into grid connection points i, j; Żᵢᵢ is a diagonal element in an impedance matrix of the grid connection point, which is an equivalent impedance of the AC system to the grid connection point i; and Żᵢⱼ is a non-diagonal element in the impedance matrix of the grid connection point, which reflects an electrical distance between the grid connection points i and j.

In some embodiments, the second short-circuit ratio index determination module 320 is specifically configured to:
determine a formula of calculating a ratio of the nominal voltage to the voltage variation; and
further derive the formula of calculating the ratio of the nominal voltage to the voltage variation, and determine the second short-circuit ratio index of the renewable energy grid-connected power system,
here the ratio of the nominal voltage to the voltage variation is calculated by a formula:

$$\frac{\vert {U}_{N} \vert}{\vert Δ {\dot{U}}_{i} \vert} = \frac{\vert {U}_{N} \vert}{\vert {\dot{Z}}_{ii} {\dot{I}}_{E , i} + {\sum }_{{j}^{′} j} {\dot{Z}}_{ij} {\dot{I}}_{E , j} \vert}$$

here U_{N} is a nominal voltage of the grid connection point i; Δ\dot{U}ᵢ is the voltage variation of the grid connection point i; İ_{E,j}, İ_{E,i} are the currents injected by the renewable energy into the grid connection points i, j; Żᵢⱼ is the diagonal element in the impedance matrix of the grid connection point, which is the equivalent impedance of the AC system to the grid connection point i; and Żᵢⱼ is the non-diagonal element in the impedance matrix of the grid connection point, which reflects the electrical distance between the grid connection points i and j.

The second short-circuit ratio index of the renewable energy grid-connected power system is calculated by a formula:

$$SCR ‐ {U}_{i} = \frac{\vert {U}_{N} {\dot{E}}_{eq , i} \vert}{\vert Δ {\dot{U}}_{i} {\dot{U}}_{i} \vert}$$

here SCR-Uᵢ is the second short-circuit ratio index of the renewable energy grid-connected power system; U_{N} is the nominal voltage of the grid connection point i; East is a no-load operation open-circuit voltage of the grid connection point i before the AC system ignores a comprehensive load and the renewable energy is grid-connected; Δ\dot{U}ᵢ is the voltage variation of the grid connection point i; and \dot{U}ᵢ is a node voltage of the grid connection point i.

In some embodiments, the CSCR determination module 330 is specifically configured to:

determine a transmission power transmitted to the AC system by the renewable energy, here the transmission power is calculated by a formula:

$${\dot{S}}_{eq , i} = ( {U}_{i} cos {θ}_{i} + {jU}_{i} sin {θ}_{i} ) ( \frac{{U}_{i} cos {θ}_{i} + {jU}_{i} sin {θ}_{i} - {E}_{eq , i}}{{E}_{eq , i} + {jX}_{eq , i}} ) *$$

$$\{ \begin{matrix}{P}_{eq , i} = \frac{{U}_{i}^{2} {R}_{eq , i} - {U}_{i} {E}_{eq , i} {R}_{eq , i} cos {θ}_{i} + {U}_{i} {E}_{eq , i} {X}_{eq , i} sin {θ}_{i}}{{R}_{eq , i}^{2} + {X}_{eq , i}^{2}} \\ {Q}_{eq , i} = \frac{{U}_{i}^{2} {X}_{eq , i} - {U}_{i} {E}_{eq , i} {X}_{eq , i} cos {θ}_{i} - {U}_{l} {E}_{eq , i} {R}_{eq , i} sin {θ}_{i}}{{R}_{eq , i}^{2} + {X}_{eq , i}^{2}}\end{matrix}$$

here \dot{S}_{eq,j} is an equivalent grid connection capacity of the renewable energy at a grid connection point i; P_{eq,i}, Q_{eq,i} are an equivalent active power and an equivalent reactive power transmitted to the AC system by the renewable energy respectively; E_{eq,i} is an equivalent potential of the AC system; R_{eq,i} is a Thevenin equivalent resistance of the AC system, and X_{eq,i} is a Thevenin equivalent reactance of the AC system; Uᵢ is a bus voltage of grid connection of the renewable energy; θᵢ is a difference between a phase angle of the bus voltage and a phase angle of the equivalent potential; and j is an imaginary number;
establish a one-variable quadratic equation about Uᵢ² according to a trigonometric function sin² θᵢ+cos² θᵢ=1:

$${U}_{i}^{4} - [ 2 ( {P}_{eq , i} {R}_{eq , i} + {Q}_{eq , i} {X}_{eq , i} ) + {E}_{eq , i}^{2} ] {U}_{i}^{2} + ( {R}_{eq , i}^{2} + {X}_{eq , i}^{2} ) ( {P}_{eq , i}^{2} + {Q}_{eq , i}^{2} ) = 0$$

$$\{ \begin{matrix}λ = \frac{{R}_{eq , i} {P}_{eq , i} + {X}_{eq , i} {Q}_{eq , i}}{{E}_{eq , i}^{2}} \\ μ = \frac{{X}_{eq , i} {P}_{eq , i} - {R}_{eq , i} {Q}_{eq , i}}{{E}_{eq , i}^{2}}\end{matrix}$$

$$Δ = 1 + 4 ( λ - {μ}^{2} ) = 0$$

here λ, μ are sensitivity factors, and A is a discriminant of the equation;
set the transmission power transmitted to the AC system by the renewable energy to be the equivalent maximum transmission power when Δ=0, here the equivalent maximum transmission power is calculated by a formula:

$${P}_{eq . i ma x} = \frac{{R}_{eq , i} ( {E}_{eq , i}^{2} + 2 {Q}_{eq , i} {X}_{eq , i} ) + {E}_{eq , i} \sqrt{{R}_{eq , i}^{2} + {X}_{eq , i}^{2}} \sqrt{{E}_{eq , i}^{2} + 4 {Q}_{eq , i} {X}_{eq , i}}}{2 {X}_{eq , i}^{2}}$$

here P_{eq,imax} is the equivalent maximum transmission power transmitted to the AC system by the renewable energy, Q_{eq,i} is the equivalent reactive power transmitted to the AC system by the renewable energy, E_{eq,i} is the equivalent potential of the AC system; R_{eq,i} is the Thevenin equivalent resistance of the AC system, and X_{eq,i} is the Thevenin equivalent reactance of the AC system; and
determine the CSCR of the renewable energy grid-connected power system, by:

$$CSCR = \frac{{\dot{S}}_{a c , i}}{\vert {P}_{eq , ima x} + {jQ}_{eq , i} \vert}$$

here \dot{S}_{ac,i} is a short-circuit capacity provided for the grid connection point i by the AC system; Q_{eq,i} is the equivalent reactive power transmitted to the AC system by the renewable energy; P_{eq,imax} is the equivalent maximum transmission power transmitted to the AC system by the renewable energy; and j is the imaginary number.

In some embodiments, the voltage support strength determination module 340 is specifically configured to:
determine an extreme value of the CSCR of the renewable energy grid-connected power system when active power and reactive power of the renewable energy grid-connected power system flow from the renewable energy into the AC system;
determine the extreme value of the CSCR as a standard for dividing strong and weak voltage support levels of the renewable energy grid-connected power system;
determine the strong voltage support level of the renewable energy grid-connected power system when the first short-circuit ratio index or the second short-circuit ratio index is greater than the extreme value of the CSCR; and
determine the weak voltage support level of the renewable energy grid-connected power system when the first short-circuit ratio index or the second short-circuit ratio index is less than the extreme value of the CSCR.

In some embodiments, the voltage support strength determination module 340 is further specifically configured to determine a stable state of the renewable energy grid-connected power system based on the first short-circuit ratio index, the second short-circuit ratio index and the CSCR.

In some embodiments, the voltage support strength determination module 340 is further specifically configured to:
determine that the renewable energy grid-connected power system operates in a stable region of P-V characteristics and the renewable energy grid-connected power system is in a stable state, when the first short-circuit ratio index or the second short-circuit ratio index is greater than the CSCR; and
determine that the renewable energy grid-connected power system operates in an unstable region of the P-V characteristics and the renewable energy grid-connected power system is in an unstable state, when the first short-circuit ratio index or the second short-circuit ratio index is less than the CSCR.

The system 300 for estimating a voltage support strength of a renewable energy grid-connected power system according to the embodiment of the disclosure corresponds to the method 100 for estimating a voltage support strength of a renewable energy grid-connected power system according to another embodiment of the disclosure, and is not elaborated here.

FIG. 4 is a schematic structural diagram of an electronic device according to an exemplary embodiment of the disclosure. As shown in FIG. 4, the electronic device 40 includes one or more processors 41 and a memory 42.

The processor 41 may be a central processing unit (CPU) or other forms of processing units with data processing capability and/or instruction execution capability, and may control other components in the electronic device to perform desired functions.

The memory 42 may include one or more computer program products which may include various forms of computer-readable storage mediums, such as a volatile memory and/or a non-volatile memory. For example, the volatile memory may include a random access memory (RAM), and/or a cache memory (cache), or the like. For example, the non-volatile memory may include a read-only memory (ROM), a hard disk, a flash memory, or the like. One or more computer program instructions may be stored on the computer-readable storage medium, and the processor 41 may execute the program instructions to implement the method for estimating a voltage support strength of a renewable energy grid-connected power system and/or other desired functions of software programs of various embodiments of the disclosure described above. In an example, the electronic device may further include an input device 43 and an output device 44 which are interconnected by a bus system and/or other forms of connection mechanisms (not shown).

Furthermore, for example, the input device 43 may further include a keyboard, a mouse, or the like.

The output device 44 may output various information to the outside. For example, the output device 44 may include a display, a speaker, a printer, a communication network and remote output devices connected thereto, or the like.

Of course, for sake of simplicity, only some of components in the electronic device related to the disclosure are shown in FIG. 4, and components such as a bus, an input/output interface, or the like are omitted. In addition, the electronic device may further include any other suitable components according to a specific application.

### Exemplary Computer Program Product and Computer-Readable Storage Medium

In addition to the above methods and devices, the embodiments of the disclosure may be a computer program product which includes computer program instructions, the computer program instructions enable a processor to execute operations of the method for estimating a voltage support strength of a renewable energy grid-connected power system according to various embodiments of the disclosure and described in the above “Exemplary method” section of the description when the computer program instructions are executed by the processor.

The computer program product may write program codes configured to perform operations of the embodiments of the disclosure in any combination of one or more programming languages which include object-oriented programming languages such as Java, C++, etc., and conventional procedural programming languages such as “C” language or similar programming languages. The program codes may be completely executed on a user computing device, partly executed on a user device, executed as a separate software package, partly executed on the user computing device and partly executed on a remote computing device, or completely executed on the remote computing device or a server.

Furthermore, the embodiments of the disclosure may also be a computer-readable storage medium, having stored thereon computer program instructions, the computer program instructions enable a processor to execute operations of the method for estimating a voltage support strength of a renewable energy grid-connected power system according to various embodiments of the disclosure and described in the above “Exemplary method” section of the description when the computer program instructions are executed by the processor.

The computer-readable storage medium may adopt any combination of one or more readable mediums. The readable medium may be a readable signal medium or a readable storage medium. For example, the readable storage medium may include, but is not limited to electric, magnetic, optical, electromagnetic, infrared or semiconductor systems, systems or devices, or any combination of the above items. More specific examples (a non-exhaustive list) of the readable storage medium include an electrical connection with one or more wires, a portable disk, a hard disk, a RAM, a ROM, an erasable programmable ROM (EPROM or a flash memory), an optical fiber, a portable compact disk ROM (CD-ROM), an optical storage device, a magnetic storage device, or any suitable combination of the above items.

Basic principles of the disclosure have been described as above in combination with specific embodiments. However, it should be noted that advantages, benefits, effects, etc. mentioned in the disclosure are only examples rather than limitations, and these advantages, benefits, effects, etc. cannot be considered as being necessary for the embodiments of the disclosure. Furthermore, specific details disclosed as above are only for purpose of providing examples and facilitating understanding, rather than limitations. The above details do not limit the disclosure to be implemented by using the above specific details inevitably.

The embodiments in the description are described in a progressive manner, and each of the embodiments focuses on descriptions of differences from other embodiments. The same or similar parts among the embodiments may refer to each other. System embodiments basically correspond to method embodiments, and thus are described relatively simply, and relevant parts may refer to descriptions of parts of the method embodiments.

Block diagrams of components, systems and devices involved in the disclosure are only illustrative examples and are not intended to require or imply that they must be connected, arranged or configured in manners shown in the block diagrams. As will be recognized by those skilled in the art, these components, systems and devices may be connected, arranged or configured in any manner. Words such as “including”, “containing”, “having”, or the like are open-ended words, refer to “including, but not limited to”, and may be used interchangeably therewith. Words “or” and “and” used here refer to a word “and/or”, and may be used interchangeably therewith, unless otherwise indicated clearly in the context. A word “such as” used here refers to a phrase “such as, but not limited to”, and may be used interchangeably therewith.

The method and system of the disclosure may be implemented in many ways. For example, the method and system of the disclosure may be implemented through software, hardware, firmware, or any combination of software, hardware and firmware. The above sequences for operations of the method are only for illustration, and the operations of the method according to the disclosure are not limited to the above specific sequences, unless otherwise specified in other ways. Furthermore, in some embodiments, the disclosure may also be implemented as programs recorded in a recording medium, and these programs include machine-readable instructions for implementing the method according to the disclosure. Therefore, the disclosure also covers a recording medium which stores programs for executing the method according to the disclosure.

It should also be noted that in the system, device and method according to the disclosure, each component or operation may be disassembled and/or recombined. These disassembly and/or recombination should be considered as equivalent solutions of the disclosure. The above descriptions of disclosed aspects are provided to enable any person skilled in the art to make or use the disclosure. Various modifications to these aspects are very apparent to those skilled in the art, and general principles defined here may be applied to other aspects without departing from the scope of the disclosure. Therefore, the disclosure is not intended to be limited to the aspects shown here, instead, has the widest range consistent with principles and novel features disclosed here.

The above descriptions have been provided for purpose of illustration and description. Furthermore, the descriptions are not intended to limit the embodiments of the disclosure to the forms disclosed here. Although multiple exemplary aspects and embodiments have been discussed above, certain variations, modifications, changes, additions and sub-combinations thereof will be recognized by those skilled in the art.

### INDUSTRIAL APPLICABILITY

According to the disclosure, firstly, the first short-circuit ratio index of the renewable energy grid-connected power system is determined based on the short-circuit capacity provided for the grid connection point by the AC system in the renewable energy grid-connected power system and the equivalent grid connection capacity of the renewable energy at the grid connection point. Then, the second short-circuit ratio index of the renewable energy grid-connected power system is determined based on the voltage variation at the position where the renewable energy is connected to the grid connection point. Secondly, the CSCR of the renewable energy grid-connected power system is determined based on parameters of the AC system and the equivalent maximum transmission power transmitted to the AC system by the renewable energy. Finally, the voltage support strength provided by the renewable energy grid-connected power system at the grid connection point is determined based on the first short-circuit ratio index, the second short-circuit ratio index and the CSCR and by using the preset voltage support strength estimation rule. The disclosure proposes a practical method for calculating the CSCR, by constructing accurate and practical short-circuit ratio indexes, and provides an accurate, rapid, intuitive and practical method and system for estimating the voltage support strength of the renewable energy grid-connected power system, by taking the CSCR as a reference point and taking the short-circuit ratio of the system as a coordinate. Therefore, the disclosure may estimate the voltage support strength of the renewable energy grid-connected power system more intuitively and simply with characteristics of accuracy and rapidity, and the method is simple and practical, which are of great significance to ensure a safe and stable operation of the renewable energy grid-connected power system.

1. A method for estimating a voltage support strength of a renewable energy grid-connected power system, comprising:
determining a first short-circuit ratio index of the renewable energy grid-connected power system based on a short-circuit capacity provided for a grid connection point by an alternating-current (AC) system in the renewable energy grid-connected power system and an equivalent grid connection capacity of a renewable energy at the grid connection point;
determining a second short-circuit ratio index of the renewable energy grid-connected power system based on a voltage variation at a position where the renewable energy is connected to the grid connection point;
determining a critical short-circuit ratio (CSCR) of the renewable energy grid-connected power system based on parameters of the AC system and an equivalent maximum transmission power transmitted to the AC system by the renewable energy; and
determining a voltage support strength provided by the renewable energy grid-connected power system at the grid connection point based on the first short-circuit ratio index, the second short-circuit ratio index and the CSCR and by using a preset voltage support strength estimation rule.

2. The method of claim 1, wherein determining the first short-circuit ratio index of the renewable energy grid-connected power system based on the short-circuit capacity provided for the grid connection point by the AC system in the renewable energy grid-connected power system and the equivalent grid connection capacity of the renewable energy at the grid connection point comprises:
determining the short-circuit capacity provided for the grid connection point by the AC system in the renewable energy grid-connected power system;
determining the equivalent grid connection capacity of the renewable energy at the grid connection point; and
determining the first short-circuit ratio index of the renewable energy grid-connected power system based on the short-circuit capacity and the equivalent grid connection capacity.

3. The method of claim 2, wherein the short-circuit capacity provided for the grid connection point by the AC system is calculated by a formula:
$${\dot{S}}_{a c , i} = \frac{{U}_{N} {\dot{E}}_{eq , i}}{{\dot{Z}}_{ii}}$$
wherein Ė_{eq,j} is a no-load operation open-circuit voltage of a grid connection point i before the AC system ignores a comprehensive load and the renewable energy is grid-connected; Żᵢᵢ is a diagonal element in an impedance matrix of the grid connection point, which is an equivalent impedance of the AC system to the grid connection point i; and U_{N} is a nominal voltage of the grid connection point i.

4. The method of claim 2, wherein the equivalent grid connection capacity at the grid connection point is calculated by a formula:
$${\dot{S}}_{eq , i} = {\dot{U}}_{i} {I}_{eq , i}^{*} = {\dot{S}}_{i} + {\sum }_{j \neq i} \frac{{\dot{Z}}_{ij}^{*}}{{\dot{Z}}_{ii}^{*}} \frac{{\dot{U}}_{i}}{{\dot{U}}_{j}} {\dot{S}}_{j}$$
wherein * represents a conjugate operation; \dot{S}ᵢ, \dot{S}ⱼ are capacities of renewable energies directly connected to grid connection points i and j; l_{eq,i} is a line current of the grid connection point i; Żᵢⱼ is a non-diagonal element in an impedance matrix of the grid connection point, which reflects an electrical distance between the grid connection points i and j; Żᵢᵢ is a diagonal element in the impedance matrix of the grid connection point, which is an equivalent impedance of the AC system to the grid connection point i; and \dot{U}ᵢ, \dot{U}ⱼ are node voltages of the grid connection points i and j.

5. The method of claim 2, wherein the first short-circuit ratio index of the renewable energy grid-connected power system is calculated by a formula:
$$S C R - {S}_{i} = \frac{{\dot{S}}_{ac , i}}{{\dot{S}}_{eq , i}} = \frac{\vert {U}_{N} {\dot{E}}_{eq , i} / {\dot{Z}}_{ii} \vert}{\vert {\dot{S}}_{i} + {\sum }_{j \neq i} \frac{{\dot{Z}}_{ij}^{*}}{{\dot{Z}}_{ii}^{*}} \frac{{\dot{U}}_{i}}{{\dot{U}}_{j}} {\dot{S}}_{j} \vert}$$
wherein SCR-Sᵢ is the first short-circuit ratio index of the renewable energy grid-connected power system; \dot{S}_{ac,j} is a short-circuit capacity provided for a grid connection point i by the AC system; \dot{S}_{eq,i} is an equivalent grid connection capacity of the renewable energy at the grid connection point i; \dot{U}ᵢ, \dot{U}ⱼ are node voltages of grid connection points i and j; U_{N} is a nominal voltage of the grid connection point i; Ė_{eq,j} is a no-load operation open-circuit voltage of the grid connection point i before the AC system ignores a comprehensive load and the renewable energy is grid-connected; Żᵢⱼ is a diagonal element in an impedance matrix of the grid connection point, which is an equivalent impedance of the AC system to the grid connection point i; Żᵢⱼ is a non-diagonal element in the impedance matrix of the grid connection point, which reflects an electrical distance between the grid connection points i and j; and \dot{S}ᵢ, \dot{S}ⱼ are capacities of renewable energies directly connected to the grid connection points i and j.

6. The method of claim 1, wherein determining the second short-circuit ratio index of the renewable energy grid-connected power system based on the voltage variation at the position where the renewable energy is connected to the grid connection point comprises:
determining a voltage order-reduction equation of the grid connection point when the renewable energy is connected to the grid connection point;
determining the voltage variation at the position where the renewable energy is connected to the grid connection point based on the voltage order-reduction equation;
determining a nominal voltage of the grid connection point; and
determining the second short-circuit ratio index of the renewable energy grid-connected power system based on the voltage variation and the nominal voltage.

7. The method of claim 6, wherein the voltage order-reduction equation of the grid connection point is:
$$[ \begin{matrix}Δ {\dot{U}}_{1} \\ ⋮ \\ Δ {\dot{U}}_{i} \\ ⋮ \\ Δ {\dot{U}}_{m}\end{matrix} ] = [ \begin{matrix}{\dot{Z}}_{11} & … & {\dot{Z}}_{1 i} & … & {\dot{Z}}_{1 m} \\ ⋮ & & ⋮ & & ⋮ \\ {\dot{Z}}_{i 1} & … & {\dot{Z}}_{ii} & … & {\dot{Z}}_{im} \\ ⋮ & & ⋮ & & ⋮ \\ {\dot{Z}}_{m 1} & … & {\dot{Z}}_{mi} & … & {\dot{Z}}_{mm}\end{matrix} ] [ \begin{matrix}{\dot{I}}_{E , 1} \\ ⋮ \\ {\dot{I}}_{E , i} \\ ⋮ \\ {\dot{I}}_{E , m}\end{matrix} ]$$
wherein Ż is an impedance matrix of the grid connection point; Δ\dot{U} is a voltage variation at the grid connection point caused when the renewable energy is grid-connected; İ_{E} is a current injected by the renewable energy into the grid connection point; and m is a serial number of the grid connection point.

8. The method of claim 7, wherein the voltage variation at the position where the renewable energy is connected to the grid connection point is calculated by a formula:
$$Δ {\dot{U}}_{i} = {\dot{Z}}_{ii} {\dot{I}}_{E , i} + {\sum }_{j \neq i} {\dot{Z}}_{ij} {\dot{I}}_{E , j}$$
wherein Δ\dot{U}ᵢ is a voltage variation of the grid connection point i; İ_{E,i}, İ_{E,j} In are currents injected by the renewable energy into grid connection points i, j; Żᵢᵢ is a diagonal element in an impedance matrix of the grid connection point, which is an equivalent impedance of the AC system to the grid connection point i; and Żᵢⱼ is a non-diagonal element in the impedance matrix of the grid connection point, which reflects an electrical distance between the grid connection points i and j.

9. The method of claim 8, wherein determining the second short-circuit ratio index of the renewable energy grid-connected power system based on the voltage variation and the nominal voltage comprises:
determining a formula of calculating a ratio of the nominal voltage to the voltage variation; and
further deriving the formula of calculating the ratio of the nominal voltage to the voltage variation, and determining the second short-circuit ratio index of the renewable energy grid-connected power system,
wherein the ratio of the nominal voltage to the voltage variation is calculated by a formula:
$$\frac{\vert {U}_{N} \vert}{\vert Δ {\dot{U}}_{i} \vert} = \frac{\vert {U}_{N} \vert}{\vert {\dot{Z}}_{ii} {\dot{I}}_{E , i} + {\sum }_{{j}^{′} i} {\dot{Z}}_{ij} {\dot{I}}_{E , i} \vert}$$
wherein U_{N} is a nominal voltage of the grid connection point i; Δ\dot{U}ᵢ is the voltage variation of the grid connection point i; İ_{E,j}, İ_{E,j} are the currents injected by the renewable energy into the grid connection points i, j; Żᵢᵢ is the diagonal element in the impedance matrix of the grid connection point, which is the equivalent impedance of the AC system to the grid connection point i; and Żᵢⱼ is the non-diagonal element in the impedance matrix of the grid connection point, which reflects the electrical distance between the grid connection points i and j,
the second short-circuit ratio index of the renewable energy grid-connected power system is calculated by a formula:
$$S C R - {U}_{i} = \frac{\vert {U}_{N} {\dot{E}}_{eq , i} \vert}{\vert Δ {\dot{U}}_{i} {\dot{U}}_{i} \vert}$$
wherein SCR-Uᵢ is the second short-circuit ratio index of the renewable energy grid-connected power system; U_{N} is the nominal voltage of the grid connection point i; Ė_{eq,j} is a no-load operation open-circuit voltage of the grid connection point i before the AC system ignores a comprehensive load and the renewable energy is grid-connected; Δ\dot{U}ᵢ is the voltage variation of the grid connection point i; and \dot{U}ᵢ is a node voltage of the grid connection point i.

10. The method of claim 1, wherein determining the CSCR of the renewable energy grid-connected power system based on parameters of the AC system and the equivalent maximum transmission power transmitted to the AC system by the renewable energy comprises:
determining a transmission power transmitted to the AC system by the renewable energy, wherein the transmission power is calculated by a formula:
$${\dot{S}}_{eq , i} = ( {U}_{i} cos θ , + {jU}_{i} sin {θ}_{i} ) {( \frac{{U}_{i} cos {θ}_{i} + {jU}_{i} sin {θ}_{i} - {E}_{eq , i}}{{R}_{eq , i} + {jX}_{eq , i}} )}^{*}$$
$$\{ \begin{matrix}{P}_{eq , i} = \frac{{U}_{i}^{2} {R}_{eq , i} - {U}_{i} {E}_{eq , i} {R}_{eq , i} cos {θ}_{i} + {U}_{i} {E}_{eq , i} {X}_{eq , i} sin {θ}_{i}}{{R}_{eq , i}^{2} + {X}_{eq , i}^{2}} \\ {Q}_{eq , i} = \frac{{U}_{i}^{2} {X}_{eq , i} - {U}_{i} {E}_{eq , i} {X}_{eq , i} cos {θ}_{i} - {U}_{i} {E}_{eq , i} {R}_{eq , i} sin {θ}_{i}}{{R}_{eq , i}^{2} + {X}_{eq , i}^{2}}\end{matrix}$$
wherein \dot{S}_{eq,j} is an equivalent grid connection capacity of the renewable energy at a grid connection point i; P_{eq,i}, Q_{eq,i} are an equivalent active power and an equivalent reactive power transmitted to the AC system by the renewable energy respectively; E_{eq,i} is an equivalent potential of the AC system; R_{eq,i} is a Thevenin equivalent resistance of the AC system, and X_{eq,i} is a Thevenin equivalent reactance of the AC system; Uᵢ is a bus voltage of grid connection of the renewable energy; θᵢ is a difference between a phase angle of the bus voltage and a phase angle of the equivalent potential; and j is an imaginary number;
establishing a one-variable quadratic equation about Uᵢ² according to a trigonometric function sin²θᵢ+cos²θᵢ=1:
$${U}_{i}^{4} - [ 2 ( {P}_{eq , i} {R}_{eq , i} + {Q}_{eq , i} {X}_{eq , i} ) + {E}_{eq , i}^{2} ] {U}_{i}^{2} + ( {R}_{eq , i}^{2} + {X}_{eq , i}^{2} ) ( {P}_{eq , i}^{2} + {Q}_{eq , i}^{2} ) = 0 \\ \{ \begin{matrix}λ = \frac{{R}_{eq , i} {P}_{eq , i} + {X}_{eq , i} {Q}_{eq , i}}{{E}_{eq , i}^{2}} \\ μ = \frac{{X}_{eq , i} {P}_{eq , i} - {R}_{eq , i} {Q}_{eq , i}}{{E}_{eq , i}^{2}}\end{matrix} Δ = 1 + 4 ( λ - {μ}^{2} ) = 0$$
wherein λ, μ are sensitivity factors, and Δ is a discriminant of the equation;
setting the transmission power transmitted to the AC system by the renewable energy to be the equivalent maximum transmission power when Δ=0, wherein the equivalent maximum transmission power is calculated by a formula:
$${P}_{eq , i max} = \frac{{R}_{eq , i} ( {E}_{eq , i}^{2} + 2 {Q}_{eq , i} {X}_{eq , i} ) + {E}_{eq , i} \sqrt{{R}_{eq , i}^{2} + {X}_{eq , i}^{2}} \sqrt{{E}_{eq , i}^{2} + 4 {Q}_{eq , i} {X}_{eq , i}}}{2 {X}_{eq , i}^{2}}$$
wherein P_{eq,imax} is the equivalent maximum transmission power transmitted to the AC system by the renewable energy, Q_{eq,i} is the equivalent reactive power transmitted to the AC system by the renewable energy, E_{eq,i} is the equivalent potential of the AC system; R_{eq,i} is the Thevenin equivalent resistance of the AC system, and X_{eq,i} is the Thevenin equivalent reactance of the AC system; and
determining the CSCR of the renewable energy grid-connected power system, by:
$$C S C R = \frac{{\dot{S}}_{ac , i}}{\vert {P}_{eq , i max} + {jQ}_{eq , i} \vert}$$
wherein \dot{S}_{ac,i} is a short-circuit capacity provided for the grid connection point i by the AC system; Q_{eq,i} is the equivalent reactive power transmitted to the AC system by the renewable energy; P_{eq,imax} is the equivalent maximum transmission power transmitted to the AC system by the renewable energy; and j is the imaginary number.

11. The method of claim 1, wherein determining the voltage support strength provided by the renewable energy grid-connected power system at the grid connection point based on the first short-circuit ratio index, the second short-circuit ratio index and the CSCR and by using the preset voltage support strength estimation rule comprises:
determining an extreme value of the CSCR of the renewable energy grid-connected power system when active power and reactive power of the renewable energy grid-connected power system flow from the renewable energy into the AC system;
determining the extreme value of the CSCR as a standard for dividing strong and weak voltage support levels of the renewable energy grid-connected power system;
determining the strong voltage support level of the renewable energy grid-connected power system when the first short-circuit ratio index or the second short-circuit ratio index is greater than the extreme value of the CSCR; and
determining the weak voltage support level of the renewable energy grid-connected power system when the first short-circuit ratio index or the second short-circuit ratio index is less than the extreme value of the CSCR.

12. The method of claim 1, further comprising: determining a stable state of the renewable energy grid-connected power system based on the first short-circuit ratio index, the second short-circuit ratio index and the CSCR.

13. The method of claim 12, wherein determining the stable state of the renewable energy grid-connected power system based on the first short-circuit ratio index, the second short-circuit ratio index and the CSCR comprises:
determining that the renewable energy grid-connected power system operates in a stable region of P-V characteristics and the renewable energy grid-connected power system is in a stable state, when the first short-circuit ratio index or the second short-circuit ratio index is greater than the CSCR; and
determining that the renewable energy grid-connected power system operates in an unstable region of the P-V characteristics and the renewable energy grid-connected power system is in an unstable state, when the first short-circuit ratio index or the second short-circuit ratio index is less than the CSCR.

14. An electronic device, comprising:
a processor; and
a memory configured to store an executable instruction of the processor, the processor configured to read the executable instruction from the memory and execute the instruction to:
determine a first short-circuit ratio index of a renewable energy grid-connected power system based on a short-circuit capacity provided for a grid connection point by an alternating-current (AC) system in the renewable energy grid-connected power system and an equivalent grid connection capacity of a renewable energy at the grid connection point;
determine a second short-circuit ratio index of the renewable energy grid-connected power system based on a voltage variation at a position where the renewable energy is connected to the grid connection point;
determine a critical short-circuit ratio (CSCR) of the renewable energy grid-connected power system based on parameters of the AC system and an equivalent maximum transmission power transmitted to the AC system by the renewable energy; and
determine a voltage support strength provided by the renewable energy grid-connected power system at the grid connection point based on the first short-circuit ratio index, the second short-circuit ratio index and the CSCR and by using a preset voltage support strength estimation rule.

15. The electronic device of claim 14, wherein, in determining a first short-circuit ratio index of the renewable energy grid-connected power system, the processor is configured to:
determine the short-circuit capacity provided for the grid connection point by the AC system in the renewable energy grid-connected power system;
determine the equivalent grid connection capacity of the renewable energy at the grid connection point; and
determine the first short-circuit ratio index of the renewable energy grid-connected power system based on the short-circuit capacity and the equivalent grid connection capacity.

16. The electronic device of claim 14, wherein, in determining the second short-circuit ratio index of the renewable energy grid-connected power system, the processor is configured to:
determine a voltage order-reduction equation of the grid connection point when the renewable energy is connected to the grid connection point;
determine the voltage variation at the position where the renewable energy is connected to the grid connection point based on the voltage order-reduction equation;
determine a nominal voltage of the grid connection point; and
determine the second short-circuit ratio index of the renewable energy grid-connected power system based on the voltage variation and the nominal voltage.

17. The electronic device of claim 14, wherein, in determining the CSCR of the renewable energy grid-connected power system, the processor is configured to:
determine a transmission power transmitted to the AC system by the renewable energy, wherein the transmission power is calculated by a formula:
$${\dot{S}}_{eq , i} = ( {U}_{i} cos {θ}_{i} + {jU}_{i} sin {θ}_{i} ) {( \frac{{U}_{i} cos {θ}_{i} + {jU}_{i} sin {θ}_{i} - {E}_{eq , i}}{{R}_{eq , i} + {jX}_{eq , i}} )}^{*} \\ \{ \begin{matrix}{P}_{eq , i} = \frac{{U}_{i}^{2} {R}_{eq , i} - {U}_{i} {E}_{eq , i} {R}_{eq , i} cos {θ}_{i} + {U}_{i} {E}_{eq , i} {X}_{eq , i} sin {θ}_{i}}{{R}_{eq , i}^{2} + {X}_{eq , i}^{2}} \\ {Q}_{eq , i} = \frac{{U}_{i}^{2} {X}_{eq , i} - {U}_{i} {E}_{eq , i} {X}_{eq , i} cos {θ}_{i} - {U}_{i} {E}_{eq , i} {R}_{eq , i} sin {θ}_{i}}{{R}_{eq , i}^{2} + {X}_{eq , i}^{2}}\end{matrix}$$
wherein \dot{S}_{eq,i} is an equivalent grid connection capacity of the renewable energy at a grid connection point i; P_{eq,i}, Q_{eq,i} are an equivalent active power and an equivalent reactive power transmitted to the AC system by the renewable energy respectively; E_{eq,i} is an equivalent potential of the AC system; R_{eq,i} is a Thevenin equivalent resistance of the AC system, and X_{eq,i} is a Thevenin equivalent reactance of the AC system; Uᵢ is a bus voltage of grid connection of the renewable energy; θᵢ is a difference between a phase angle of the bus voltage and a phase angle of the equivalent potential; and j is an imaginary number;
establish a one-variable quadratic equation about Uᵢ² according to a trigonometric function sin²θᵢ+cos²θᵢ=1:
$${U}_{i}^{4} - [ 2 ( {P}_{eq , i} {R}_{eq , i} + {Q}_{eq , i} {X}_{eq , i} ) + {E}_{eq , i}^{2} ] {U}_{i}^{2} + ( {R}_{eq , i}^{2} + {X}_{eq , i}^{2} ) ( {P}_{eq , i}^{2} + {Q}_{eq , i}^{2} ) = 0 \\ \{ \begin{matrix}λ = \frac{{R}_{eq , i} {P}_{eq , i} + {X}_{eq , i} {Q}_{eq , i}}{{E}_{eq , i}^{2}} \\ μ = \frac{{X}_{eq , i} {P}_{eq , i} - {R}_{eq , i} {Q}_{eq , i}}{{E}_{eq , i}^{2}}\end{matrix} Δ = 1 + 4 ( λ - {μ}^{2} ) = 0$$
wherein λ, μ are sensitivity factors, and Δ is a discriminant of the equation;
set the transmission power transmitted to the AC system by the renewable energy to be the equivalent maximum transmission power when Δ=0, wherein the equivalent maximum transmission power is calculated by a formula:
$${P}_{eq , i max} = \frac{{R}_{eq , i} ( {E}_{eq , i}^{2} + 2 {Q}_{eq , i} {X}_{eq , i} ) + {E}_{eq , i} \sqrt{{R}_{eq , i}^{2} + {X}_{eq , i}^{2}} \sqrt{{E}_{eq , i}^{2} + 4 {Q}_{eq , i} {X}_{eq , i}}}{2 {X}_{eq , i}^{2}}$$
wherein P_{eq,imax} is the equivalent maximum transmission power transmitted to the AC system by the renewable energy, Q_{eq,i} is the equivalent reactive power transmitted to the AC system by the renewable energy, E_{eq,i} is the equivalent potential of the AC system; R_{eq,i} is the Thevenin equivalent resistance of the AC system, and X_{eq,i} is the Thevenin equivalent reactance of the AC system; and
determine the CSCR of the renewable energy grid-connected power system, by:
$$C S C R = \frac{{\dot{S}}_{ac , i}}{\vert {P}_{eq , i max} + {jQ}_{eq , i} \vert}$$
wherein \dot{S}_{ac,j} is a short-circuit capacity provided for the grid connection point i by the AC system; Q_{eq,i} is the equivalent reactive power transmitted to the AC system by the renewable energy; P_{eq,imax} is the equivalent maximum transmission power transmitted to the AC system by the renewable energy; and j is the imaginary number.

18. The electronic device of claim 14, wherein, in determining the voltage support strength provided by the renewable energy grid-connected power system at the grid connection point, the processor is configured to:
determine an extreme value of the CSCR of the renewable energy grid-connected power system when active power and reactive power of the renewable energy grid-connected power system flow from the renewable energy into the AC system;
determine the extreme value of the CSCR as a standard for dividing strong and weak voltage support levels of the renewable energy grid-connected power system;
determine the strong voltage support level of the renewable energy grid-connected power system when the first short-circuit ratio index or the second short-circuit ratio index is greater than the extreme value of the CSCR; and
determine the weak voltage support level of the renewable energy grid-connected power system when the first short-circuit ratio index or the second short-circuit ratio index is less than the extreme value of the CSCR.

19. A non-transitory computer-readable storage medium, having stored thereon a computer program, the computer program executing a method for estimating a voltage support strength of a renewable energy grid-connected power system, comprising:
determining a first short-circuit ratio index of the renewable energy grid-connected power system based on a short-circuit capacity provided for a grid connection point by an alternating-current (AC) system in the renewable energy grid-connected power system and an equivalent grid connection capacity of a renewable energy at the grid connection point;
determining a second short-circuit ratio index of the renewable energy grid-connected power system based on a voltage variation at a position where the renewable energy is connected to the grid connection point;
determining a critical short-circuit ratio (CSCR) of the renewable energy grid-connected power system based on parameters of the AC system and an equivalent maximum transmission power transmitted to the AC system by the renewable energy; and
determining a voltage support strength provided by the renewable energy grid-connected power system at the grid connection point based on the first short-circuit ratio index, the second short-circuit ratio index and the CSCR and by using a preset voltage support strength estimation rule.

20. (canceled)
